(19) United States
(12) Patent Application Publication
(10) Pub. No.: US 2023/0098270 A1
(43) Pub. Date: Mar. 30, 2023

(54) PRECURSORS FOR HIGH-TEMPERATURE DEPOSITION OF SILICON-CONTAINING FILMS

(71) Applicant: Lam Research Corporation, Fremont, CA (US)

(72) Inventors: Douglas Walter Agnew, Portland, OR (US); Adrien LaVoie, Newberg, OR (US)

(21) Appl. No.: 17/759,676

(22) PCT Filed: Feb. 3, 2021
(86) PCT No.: PCT/US2021/016376

§ 371 Date: Jul. 28, 2022

Related U.S. Application Data
(60) Provisional application No. 62/971,680, filed on Feb. 7, 2020.

(51) Int. Cl. H01L 21/02; C23C 16/40; C23C 16/455

(52) U.S. Cl. CPC H01L 21/02164; C23C 16/401; H01L 21/02211; H01L 21/0228; C23C 16/45553; C23C 16/45527; C23C 16/45536

(57) ABSTRACT

Silicon-containing films, such as silicon oxide films, having high quality are deposited on semiconductor substrates using reactions of silicon-containing precursors in high temperature ALD processes. In some embodiments, provided precursors are suitable for deposition of silicon-containing films at temperatures of at least about 500° C., such as greater than about 550° C. For example, silicon oxide can be deposited at high temperature by a reaction of the silicon-containing precursor with an oxygen-containing reactant (e.g., O₃ O₂, H₂O) on a substrate's surface. In some implementations, the suitable precursor includes at least one silicon-silicon bond, at least one leaving group (e.g., a halogen), and, optionally, at least one electron-donating group (e.g., an alkyl). The precursors are suitable, in some implementations, for both thermal ALD and for PEALD. In some embodiments, a single precursor is used in both thermal ALD and in PEALD during deposition of a single silicon oxide film.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD OF THE INVENTION

This invention pertains to methods of semiconductor device manufacturing. Specifically, embodiments of this invention pertain to precursors used for deposition of silicon-containing films in semiconductor processing.

### BACKGROUND

In integrated circuit (IC) fabrication, deposition and etching techniques are used for formining patterns of materials, such as for forming metal lines embedded in dielectric layers. Some patterning schemes require conformal deposition of inaterials, where the deposited layer should follow the contour of protrusions and/or recessed features on the surface of the substrate. Atomic layer deposition (ALD) is often a preferred method of forming conformal films on a substrate, because ALD typically relies on adsorption of one or more reactants (precursors) to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, this method can provide thin conformal layers having excellent step coverage.

Chemical vapor deposition (CVD) is another deposition method widely used in semiconductor processing. In CVD, the reaction occurs in the volume of the process chamber, and is not limited by the amount of reactants adsorbed to the substrate. As a result, CVD -deposited films are Mien less conformal than ALD films. CVD is typically used in applications where step coverage is less import:mt.

ALD and CVD may employ plasma to promote the reactions of the deposition precursors resulting in the formation of the desired films. The methods that make use of the plasma are known as plasma enhanced ALD (PEALD) and plasma enhanced CVD (PECVD). The methods that do not employ plasma are referred to as thermal ALE) and thermal CV!).

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicdly admitted as prior art against the present disclosure.

### SUMMARY

Methods for depositing silicon-containing films, such as silicon oxide, are provided. The methods, in some embodiments, involve deposition at high temperatures of at least about 500° C., such as of at least about 550° C. (e.g. about 550° C. and greater than about 550° C.), such as of at least about 600° C. Stable silicon-containing precursors suitable for depositions at temperatures of at least about 500° C., such as at temperatures of about 550-700°, are provided. Precursors that provide surface-only desired reactivity at these temperatures and that can he used in both thermal ALD and PEALD are provided. High temperature deposition can be utilized to deposit silicon-containing films with superior quality. For example, silicon oxide deposited by high temperature ALD can have desirable characteristics for integrated circuit fabrication such as low wet etch rate, low leakage current, high breakdown field and low concentration of impurities that arc often unattainable at lower temperatures. In some embodiments, silicon oxide films obtained by high temperature deposition as described herein have one or more of the following characteristics: concentration of impurities of less than about 1 atomic % (where hydrogen concentrations are excluded from calculation), density of at least about 2.23 g/cm³ (e.g., about 2.23-2.29 g/cm³, such as about 2.26 g/cm³), wet etch rate of less than about 4 nm/min in aqueous hydrofluoric acid (HF) having a concentration of 289 mM, leakage current of less than about 1×10⁻¹⁰A/cm² at 2MV, and a breakdown field of greater than about: 10 MV/cm. In some embodiments the deposited silicon oxide films provided herein have all of the characteristics listed above.

Many silicon-containing precursors that are conventionally used for low temperature ALD, exhibit: thermal decomposition at high temperatures, and are unsuitable for high temperature ALD. Further, many conventional silicon-containing precursors are not suitable for both thermal and plasma enhanced depositions.

In one embodiment a method of forming a silicon-containing layer on a semiconductor substrate is provided, where the method includes: (a) exposing the semiconductor substrate to a silicon-containing precursor in a process chamber, (h) exposing the semiconductor substrate to a reactant in the process chamber; and (c) reacting the silicon- containing precursor with the reactant on a surface of the semiconductor substrate to form at least a portion of the silicon-containing layer, wherein operations (a)-(c) are pertbrined at a temperature of at least about 500° C., where the silicon-containing precursor is a compound that has at least one Si—Si bond; at least one Si—X bond, wherein Xis selected from the group consisting of a halogen, triflate, tosylate, CN, N₃, and NR₁R₂ wherein R₁ and R₂ are independently selected from the group consisting of H, and an alkyl, wherein R₁ and R₂ are either linked to form a cyclic ring structure or not linked; and at least one Si-R bond, wherein R is selected tom the group -consisting o.f H, and an alkyl,

In another embodiment a method of forming a silicon-containing, layer on a semiconductor substrate is provided, where the method includes: (a) exposing the semiconductor substrate to a silicon-containing precursor in a process chamber, (h) exposing the semiconductor substrate to a reactant in the process chamber; and. (et reacting the silicon-containing precursor with the reactant on a surface of the semiconductor substrate to form at least a portion of the silicon-containing layer, wherein operations (a)-(c) are performed at at temperature of at least about 500° C., and wherein the silicon-containing precursor is a compound that has at least one silicon atom that fomis bonds with at least two nitrogen atoms, wherein the at least two nitrogen atoms are linked to form a cyclic ring.

In another embodiment a method of farming a Siliconcontaining layer on a semiconductor substrate is provided, where the method includes: (a) exposing the semiconductor substrate to a silicon-containing precursor in a process chamber, (b) :exposing the semiconductor substrate to a reactant in the process chamber; and (c) reacting the silicon-containing precursor with the reactant on a surface of the semiconductor substrate to form at least a portion of the silicon-containing layer, wherein opertations (a)-(c) are performed at a temperature of at least about 500° C., and wherein the silicon-containing, precursor is a compound that has at least one nitrogen atom that forms bonds with at least two silicon atoms.

In another embodiment a method of forming a silicon-containing layer on a semiconductor substrate is provided, where the method includes: (a) exposing the semiconductor substrate to a silicon-containing precursor in a process chamber, (b) exposing the semiconductor substrate to a reactant in the process chamber; and (c) reacting the silicon-containing precursor with the reactant on a surface of the semiconductor substrate to form at least a portion of the silicon-containing layer, wherein operations (a)-(c) are performed at a temperature of at least about 500 T, and wherein the silicon-containing precursor is a compound that lin at least one silicon atom that forms a bond with a moiety selected from the group consisting of —N₃, —CN, —OTf (triflate), and —OTs (tosylate).

In another embodiment a method of forming a silicon-containing layer on a semiconductor substrate is provided, where the method includes: (a) exposing the semiconductor substrate to a silicon-containing precursor in a process chamber, (b) exposing the semiconductor substrate to ;a re;actant in the process chamber; and (c) reacting the si Ikon-containing precursor with the reactant on a surface of the semiconductor substrate to form at least a portion of the silicon-containing:layer, wherein operations (a)-(c) are performed at a temperature of at least about 500° C., and wherein the silicon-containing precursor is a compound that has at least one silicon atom that forms bonds with at least two oxygen atoms, wherein the at least two oxygen aatotfas are linked to form a cyclic ring.

In another embodiment a method of forming a silicon-containing layer on a semiconductor substrate is provided, where the method includes: a) exposing the semiconductor substrate to a silicon-containing precursor in a process chamber, (b) exposing the semiconductor substrate to a reactant in the process chamber; and (c) reacting the silicon- containing precursor with the reactant on a surface of the semiconductor substrate to form at least a portion of the silicon-containing layer, wherein operations ta) (c) are performed at a temperature of at least about 500 and wherein the silicon-containing precursor is a compound that has at least one silicon atom that is part of a cyclic ring.

In some embodiments, methods provided herein are integrated with photolithographic patterning methods and further include: applying photoresist to the workpiece, exposing the photoresist to light, patterning the photoresist and transferring the pattern to the workpiece, and selectively removing the photoresist from the work piece.

In another aspect an apparatus is provided, where the apparatus includes a process chamber having an inlet for admitting a silicon-containing precursor into the process chamber and a substrate support, where the apparatus further includes a controller having program instruct for causing deposition of silicon-containing films according to any of the methods provided herein,

In another aspect, a system is provided, where the system includes a deposition apparatus described herein and a stepper,

In another aspect, a non-transitory computer machine-readable medium comprising program instructions for control of a deposition tool is provided, where the program instructions include. code h performing steps of any it the methods provided herein.

These and other aspects of implementations of the subject matter described in this specification are set forth in the accompanying drawings and the description below.

### BRIEF DESCRIPTION OF THE DRAWINGS

FIG. 1 provides examples of silicon-containing precursors according to an embodiment provided hereen.

FIG. 2 provides examples of silicon-containing precursors according to another embodiment provided herein.

FIGS. 3A and 3B provide examples of silicon-containing precursors according to embodiments provided herein.

FIG. 4 is a process flow diagram for a method of forming silicon oxide films according to an embodiment provided herein.

FIG. 5 is a process flow diagram for a method of forming silicon oxide films according to an embodiment provided herein.

FIG. 6 is a process flow diagram for a method of forming silicon oxide films using a single precursor via both thermal ALD and PEALD.

FIG. 7 is a schematic presentation of an apparatus that is suitable for depositing silicon-containing films, according to an embodiment provided herein.

FIG. 8 shows a schematic view of a multi-station processing system according to an embodiment provided herein.

FIG. 9 shows a schematic view of a multi-station processing system according to an embodiment provided herein.

### DETAILED DESCRIPTION OF THE PREFERRED EMBODIMENTS

Methods and precursors for depositing high quality silicon-containing films on semiconductor substrates at high temperatures are provided. Provided methods and precursors can lx used, for example, for depositing a blanket silicon-containing layer (g silicon oxide layer) on a planar substrate, or for depositing a conformal silicon-containing layer on a substrate having one or more recessed or protruding features. The semiconductor substrate prior to deposition of the film may include an exposed Iayer of dielectric and/or metal on its surface. The methods arc particularly useful for depositing thin silicon-containing films in a controlled manner. For example, high quality conformal films with thicknesses of between about 0.5-250 nm can he deposited.

The methods can be used for deposition of a variety of silicon-containing niatuials including, but not limited to silicon oxide (SiOₓ), silicon nitride (SiNₓ), silicon carbide (SiCₓ), silicon oxynitride (SiOₓN_{y}), and silicon oxycarbide (SiOₓC_{y}), where x and y indicate that the stoichiometry of these compounds may vary. Provided precursors and methods are particularly suitable hu deposition of silicon oxide, such as high quality silicon oxide with low levels of incorporation of other elements. Deposition at high temperature, such as at temperatures of at team. about 500° C., such at least about 550° C., is often needed in order to produce high quality silicon oxide films having high purity. Precursors that exhibit clean reactivity at high temperatures, with low levels of decomposition, are provided herein. It is understood that the described silicon-containing precursors can also be used for depositions at lower temperatures and for deposition of films other than high quality silicon oxide. Further, provided precursors arc suitable for both thermal and plasma cnhaneed depositions, where both thermal and plasma enhanced depositions can be conducted at, high temperature of at least about 500° C., such as about 500-800° C., e,g., about 550-700° C. The temperatures recited herein refer to temperatures measured proximate the substrate, It is understood that the precursors described herein can ^{b} used for depositions at lower tempecitures than 500° C.

In some embodiments at least one step during deposition is conducted at high temperature. In other embodiments the entire deposition, which may include multiple reactant dosing and purging steps is performed at high temperature.

“Silicon oxide” as used herein, refers to a material that consists essentially of silicon (Si) and oxygen (O). Other elements (e,g., C, and N) can be present in silicon cntide in small quantities (e.g., with a total eonterit of less than about 15 atomic %, or less than iabout 10%, where hydrogen is not included in the calculation). Silicon oxide typically is SiO₂, although deviations from 1:2 (silicon:oxygen) stoichionactry may be possible. “High purity silicon oxide” as used herein refers to silicon oxide that includes less than about 1 atomic carbon, less than about 0.1% nitrogen, and less than about 0.1% of other elements, where hydrogen is not included in the calculation. In some embodiments, high purity silicon oxide includes less than about 1 atomic % of elements other than silicon and oxygen (where hydrogen is not included in the calculation).

Silicon nitride (SiNₓ), silicon carbide (SiCₓ), oxynitride (SiOₓN_{y}), and silicon oxvcarbide (SiOₓC_{y}) refer to materials that respectively consist essentially of silicon and nitrogen (SiNₓ), silicon and carbon (SiCₓ), silicon, oxygen and nitrogen (SiOₓN_{y}), and silicon oxygen and carbon (SiOₓC_{y}). Other elements may be present in these compounds in small quantities, e,g., in an amount of less than about 10% atomic, where hydrogen is excluded from the calculation,

The term “semiconductor substrate” as used herein refers to a substrate at any stage of semiconductor device fabrication containing a semiconductor material anywhere within its structure. It is understood that the semiconductor material in the semiconductor substrate does not need to be exposed, Semiconductor wafers haying a plurality of layers of other materials (e.g., dielectrics) covering the semiconductor material, are examples of semiconductor substntes. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various ithicles such as printed circuit boards and the like.

The tern, “about” when used in reference to numerical values includes a range of ±10% of the recited numerical value, unless otherwise specified.

The term “alkyl”, as used herein, refers to saturated substituents containing exclusively earbon and hydrogen atoms. Alkyls include both linear, branched and cyclic groups. Examples of linear alkyl groups include without limitation, methyl groups, ethyl groups n-propyl groups, n-butyl groups, etc. Examples of branched alkyls groups include without limitation, isopropyl, isobutyl, sec-butyl, and i-butyl. Examples of cycloalkyls include without limitation, cyclopropyl groups, cyclopentyl groups, cyclohexyl groups, etc.

The term “alkylamino”, as used herein, refers to NR₂ group, wherein at least one R is an alkyl, and each R is independently selected from H and an alkyl. Examples of alkylamino substittients include dimethylamino and diethylaminci substituents,

The term “independently selected”, when referring to R substituent selection in a molecule containing multiple R groups, means that the selection of R substituents at different atoms of a molecule is independent and that the selection of R substituents at one atom having multiple R substituents is also independent. In molecules containing multiple R groups, R groups may be same or different.

Silicon-containing films with controlled thicknesses can be deposited on semiconductor substrates by sequentially exposing the substrate to a silicon-containing precursor and to a reactant, where the reactant reacts with the silicon-containing precursor and forms a film of desired composition. The reactions are typically limited by the amount of a silicon-containing precursor and/or reactant residing on the surface of the substrate, and are typically repeated as many times as necessary for depositing a film with desired thickness, For example, silicon oxide films can be deposited by sequentially exposing, the substrate to a silicon-containing precursor and an oxygen-containing reactant, such as O₂, O₃, H₂O, H₂O₂, and N₂O, where die reactant may be optionally activated in a plasma, flowever, when deposition occurs at relatively low temperature te,g., it less than thorn 500° C.), the deposited silicon oxide often has low quality. This stems largely from the low thermal energy of the system, wInch in turn leads to such problems as hiss film density, lowered reactivity of Si-containing precursor on the surface, and increased atomic impurities as a consequence of more challenging byproduct removal, in order to deposit high quality silicon oxide, deposition often needs to be performed at temperatures of at least about 500° C., such as at least about 550° C. Many silicon-coritaining precurSors, however, are prone to decomposition n high temperatures, For example, bis(tert-butylamino)silarte (BTBAS) exhibits decomposition at temperatures of greater than about 550° C.

Several classes of silicon-containinh precursors that can be used for deposition of silicon-containing films at high temperature are provided. For example, precursors that are suitable for depositions at a temperature of at least about 500° C., such as at least about 550° C. such as at about 500-800° C., e.g., 550-700° C. are provided. in some embodiments, a single precursor is used for both PEALD and thermal ALD, where both plasma-assisted and thermal deposition are conducted in one reactor.

### Precursors Containing Si—Si Bond

In one aspect, a silicon-eontainintlf precursor suitable for high temperature deposition is a compound that has at least one Si—Si bond, at least one Si—X bond, wherein X is selected from the group consisting of a halogen (e.g., Cl, Br, and; or I), trifiate (CF₃SO₃), tosylate (CH₃C₆H₄SO₂), CN, N₃, and NR₁R₂, wherein R₁ and R₂ are independently selected from the group consisting of H. and an alkyl, wherein R₁ and R₂ are either linked to form a cyclic ring structure or not linked; and at least one Si-R bond, wherein R is selected from the group consisting of and an alkyl. In some embodiments alkyls are C1-C4 alkyls, such as methyl, ethyl, n-propyl, isopropyl, n-butyl, sec-butyl, or t-butyl.

In some embodiments, the silicon-containing precursor is SiₙR₍₂ₙ₊₁₎X, where n is an iatcoer selected from 2 to 10. and where each R is the same or different and is independently selected from the group consisting of H, an alkyl, an alkenyl, and an alkynyl.

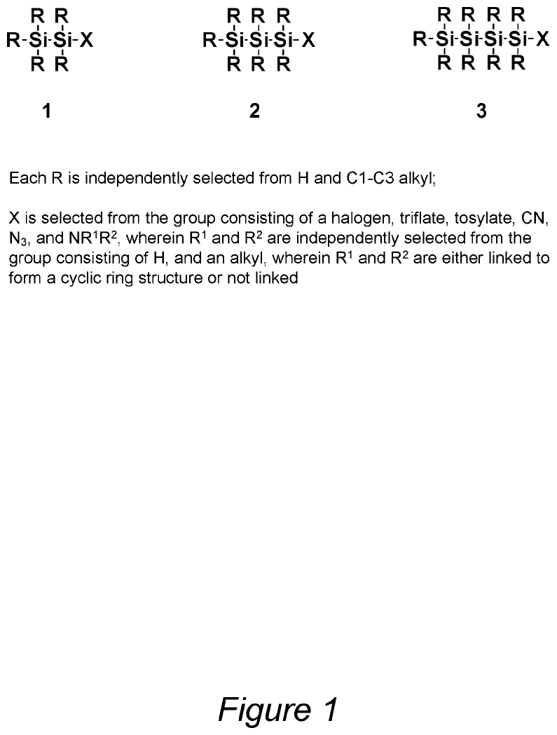

Examples of more specific suitable precursors of this type include compounds 1, 2. and 3, shown in FIG. 1, where each R is the same or different and is independently selected from H and a C1-C3 alkyl (e.a,, methyl, ethyl, n-propyl, isopropyl). Specific examples include 1-chlorodisilane, -dimethylaminodisilane, 1-diethylaminotrisilane, and 1-bromotenasilane.

In some embodiments the silicon-containing precursor includes at least one silicon atom that is part of a cycle.

In some embodiments, suitable precursors contain two or more X groups. For example 1,2-bis(diisopropylamino)disilane (BDIPADS) contains two dialkylamino substiments.

Haloalkyldisilanes can be purchased from chemical suppliers such as Millipore Sigma or Gelest. Amine-substituted shares or those including pseudohalogen groups can be prepared under inert atmosphere via nucleophilic substitution of a chloroalkylpersilane. lternatively, substituted monosilanes can be reduced with an alkali metal, such as lithium, and coupled with a second substituted silage to form a disilanc precursor, Trisilancs and tetrasilane precursors can be formed under similar conditions with an excess of alkali metal reductant.

### Precursors Containing N—Si—N Motif

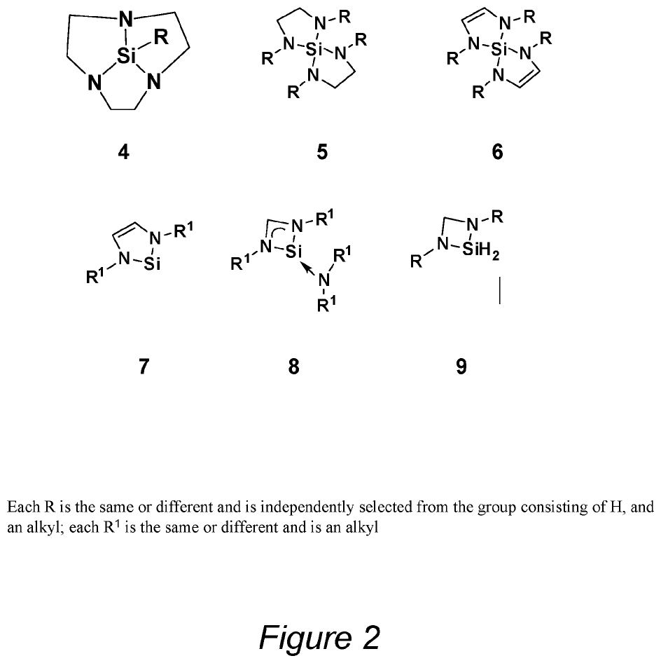

In another aspect, a silicon-containing precursor that is suitable for high temperature deposition is a compound that contains at least one silicoll atom that forms bonds with at least two nitrogen atoms, wherein the at least two nitrogen atoms are linked to form a cyclic ring. The cyclic ring includes the silicon atom and both nitrogen atoms, and may be, for example, 4-membered, 5-membered, or 6 membered. In some embodiments, the precursor includes more than one of such rings. For example, compound 4 shown in FIG. 2, based on 1,4,7-trizacyclononane (TACN) has four of such rings.

Examples of suitable compounds having N—Si—N motif are shown in FIG. 2, where in compounds 4, 5, 6, 7.8, and 9 each R is the same or different and is independently selected from the group consisting of H, and an alkyl, and each R is the same of different and is an alkyl. In some embodiments, the alkyls are C1-C4 alkyls (e.g,, methyl, ethyl, a propyl, or a butyl). Tlie illustrated compounds are based on TA.CN (compound 4), cthylenediamines (compound 5), 1,4-diazahuta-1,3-dienes (DAD) (compounds 6 and 7) and amidines (compound 8). These compounds can be prepared by reacting silicon halides with corresponding amines or diazabutadiene. In some embodiments compounds of silicon and 1,4,7-trimethyl-1,4,7-triazacyclononane (Me₃TACN) are provided, where Me₃TACN acts as a tridentate. ligand, hi one implementation the compound contains Si(Me₃TACN)X₃ cation, where X is a halogen (e, g,, F). Such compound can be prepared by a reaction of SiF₄ with Me₃TACN under anhydrous conditions.

In some embodiments suitable compounds haying N—Si—N motif arc adducts containing 2,2-bipyridine (bipy), 1,10-phenantrolitle (phen) in NN,N′N′-tetramethylethylenediamine (TMEDA). Examples of such compounds include SiX₄bipy, and SiX₄TMEDA where each X is independently selected from a group consisting of a halogen (e.g., Cl or Br), H, and an alkyl (e.g., methyl or ethyl). Specific examples include SiH₂Cl₂(bipy), SiHCl₃(bipy), SiCl₃Me(bipy), SiCl₂Me(bipy), SiCl₃H(TMEDA), and SiCl₂H₂(TMEDA). These compounds can be synthesized by reacting a silicon-containing starting material (e.g., H₂SiCl₂, HSiCl₃, MeSiCl₃) with a desired ligand bipy, phen, or TMEDA).

In some embodiments the silicon-containing precursor is a silylene (a divalent, dicoordinate silicon species). Examples of silylenes are compounds 7 and 8 shown in FIG. 2. Stability of silylenes is typically enhanced by presence of bulky groups. In some embodiments R¹ in compound 7 is a sterically bulky group such as /-butyl. A specific example of such silylene is N,N′-di-tert-butyl-1,3-diaza-2-silacyclopent-4-en-2-ylidene. These compounds can be obtained by a reaction of silicon (IV) halide (e.g., SiCl₄) with a lithiated N,N′-di-tert-butyl-1,4-diazabutadiene, followed by a reduction by alkali metal or potassium graphite to produce the silicon (II) compound 7.

### Precursors Containing O—Si—O Motif

In another aspect, a silicon-containing precursor that is suitable for high temperature deposition is a compound that contains at least one silicon atom that forms bonds with at least two oxygen atoms, wherein at least ts.vo oxygen atoms are linked to form at cyclic ring. The cyclic ring includes the silicon atom and both nitrogen atoms, and may be, for example, 4-membered, 5-membered, or 6 membered. In some embodiments, the precursor includes more than one of such rings. For example, silicon compounds with β-diketonate ligands (e,g., with acetyl acetonate) may be used. In one embodiment, the compound has a formula Si(A)₃X, where A is a substituted or unsubstituted acetylacetonate, and X is a halogen (e.g., chloride). In another embodiment, the compound has a formula Si(A)₂RX, where A is a β-diketonate (e.g., substituted or unsubstituted .:rectylacctonate), X is a halogen (e.g., chloride), and R is an alkyl (e.g., methyl). ,Acetylacetonate silicon compounds can be prepared, for example, via a reaction of silicon halide (e.g., SiCl₄) with acetylacetorie or acetylacetonate. In another embodiment the compound is Si(A)R₃, where A is a β-diketonate (e.g., acetylacetonate or dibenzoylmethane), and each R is independently selected from the group consisting of an alkyl, and haloalkyl (e.g., CF₃)

### Precursors Containing Si—N—Si Motif

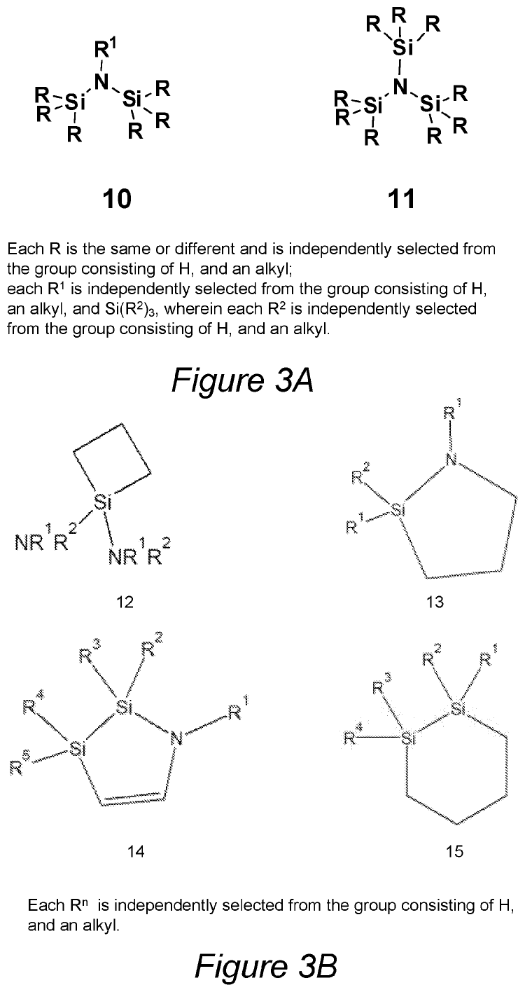

In another aspect, a silicon-containing precursor that is suitable tar high temperature deposition is a compound that: contains at least one nitrogen atom that: forms bonds with at least two silicon atoms. In some embodiments the precursor is compound 10 shown in FIG. 3A, where each R is the same or different and is independently selected from the group consisting of H, and alkyl, and wherein each le is independently selected from the group consisting of H, alkyl, and Si(R)₃, where diel R² is independently selected tram the group consisting of H, and an alkyl. In some embodiments alkyls are C1-C4 alkyls, such as C1-C3 alkyls. Specific examples of compounds 10 include tris(trimethylsiyl)amine, trisilylamine, isopropyl(disilyl)amine, ethyl-bis(trimethylsiyl)amine, di silylbydrazine. In some implementations precursors of formula 10 have structure 11 as shown in FIG. 3A. Precursors of this class can be prepared, for example, from a haloalkylsilane and the corresponding base under acidic conditions. For example, isapropylamine can be stirred in the presence of excess HCI with chlorotrimethylsilane to form isopropykunino-trimethyl-silane.

### Cyclic Precursors

In another aspect, a silicon-containing precursor that is suitable for high temperature deposition is a compound that contains at least one silicon atom that is part of a cyclic ring. Examples of rings include 4-membered, 5-membered, 6-membered, and 7-membered rings. In some embodiments at leist one silicon atom forms bonds with two carbon zatoms; where the two carbon atoms are linked to form a cyclic ring. In some embodiments, the at least one silicon atom further fatms bonds with one or two nitrogen atoms. An example of such precursor is precursor 12 shown in FIG. 3B, where R¹ and R² are same or different and are independently selected from the group consisting of an alkyl (e.g., C1-C4 alkyl), and H.

In some embodiments at least one silicon atom forms bonds with a carbon atom and a nitrogen atom, where the carbon atom and the nitrogen atom are linked to form a cyclic ring, An example of such precursor is precursor 13 shown in FIG. 3B, where R¹ and R² are same or different and are independently selected from the group consisting of an alkyl (e.g., C1-C4 and H.

In some embodiments at least one silicon atom forms bonds with a carbon atom and a silicon atom, where the carbon atom and the silicon atom are linked to form a cyclic ring. Examples of such precursors are precursor 14 and 15 shown in FIG. 3B, where R¹-R⁵ are same or different and are independendy selected from. the group consisting of an alkyl (e,g., C1-C4 alkyl), and H.

Specific examples of cyclic compounds include 1,1,2,2-tetraniethyl-1,2-disiktcyclohexanc, and 1,1-bis(ethylaminol-1-silacyclobutane. Precursors of this type can be prepared from condensation of linear haloalkyldisilanes. For example, 1,3-bis(chlorodimethyl)butane is condensed over Na/K alloy to provide 1,1,2,2-tetramethyl-1,2-disilacyclohexane

### Precursors Containing Pseudohalogen Leaving Groups

In another aspect, silicon-containing precursors are provided, where the precursor contains one or more pseudohalogen leaving groups bonded to silicon. In a specific implementation the precursor contains at least one silicon atom that forms a bond with a moiety selected from the group consisting of —N₃, —CN, —OTf (tritlate), and —OTs (tosylate). In one implementation the silicon-containing precursor is wherein each X is independently selected from the group consisting of —N₃, —CN, —OTf (triflate), and —OTs (tosylate), each R is independently selected from the group consisting of zul alkyl, and NR¹R², wherein each R¹ and R² is independently selected from the group consisting of and an alkl, wherein R¹ and R² are either linked to form a cyclic ring structure or not linked, and wherein n is 1-3, m is 1-3, and n+m is 4. Compounds of this type are typically prepared via salt metathesis, for eximple, sodium. trifluoromethanesulfonate is stirred with dialkyl(isopropylamino)chlorosilane to provide dialkyl(isopropylamino)silyl-trifluctromethanesulfonate and NaCl.

### Moieties Enhancing Stabilky and Desired Surface Reoctivily

The stability of compounds at high temperature and the desired reactivity are believed to be enhanced by a presence of at least one electron-donating group (e,g., an alkyl) bonded to silicon, and at least one leaving group bonded to silicon. Examples of suitable leaving groups include halogens (such as Cl, Br, and I) —N₃, —CN, —OTf (triflate), and —OTs (tosylate). Another example of a suitable leaving group is an NR¹R² amino group, where each R³ and R² is independently selected ftom the group consisting of H, and an alkyl, wherein R¹ and R² are either linked to form a cyclic ring structure or not linked. In one embodiment the silicon-comaining precursor is a compound of any of the classes described herein, which has at least one alkyl substituent and at least one leaving group as described above.

Without wishing to be bound by a specific theory on compound stability, it is believed that the stability of precursors can be enhanced by selecting precursors without silicon-hydrogen bonds. In one embodiment the silicon-containing precursor is a compound of any of the classes described herein, which does not have silicon-hydrogen bonds. Selection of suitable precursors is, however, not limited. by the described theories on stability. All ylated halosilanes are commercially available from a number of suppliers, such as Millipore Sigma Pseudohalogen substitution is accomplished via salt metathesis with the appropriate alky lhalos i lane.

MethodS

The silicon-containing precursors provided herein can be used for high-temperature deposition of silicon-containing films in both thermal and plasma enhanced ALD. sonic embodiments the methods involve exposing the semiconductor substrate to a silicon-containing precursor provided befOill, exposing the semiconductor substrate to a reactant (optionally activated in a plasma), and reacting the silicon-containing precursor on the surface of the semiconductor substrate with the reactant to form at least a portion of a desired silicon-containing layer. The entire deposition process (exposures of the substrate to the reactant and to the silicon-containing precursor, and the reaction) can be performed at high temperature of at least about 500° C., such as of at least about 550° C., e.g., about 550-700° C. In some embodiments, at least one of the deposition steps is performed at high temperature. The deposition can be pertlarmed at a pressure of between about 50 milltorr-about 760 Torr. Preferably the deposition is performed at subatmospheric pressure, e.g.., at a pressure of between about 50 mTorr-200 Torr.

When the reactant is activated in a plasma, the plasma may be formed remotely (outside the process chamber housing the substrate), and the plasma-activated reactant may be introduced to the process chamber. In other embodiments the plasma is a direct plasma formed in to process gas containing the reactant m the process chamber housing the substrate.

Plasma may be formed, in some embodiments, using single frequency high frequency radio frequency (HF RF) plasma generation. In other embodiments that utilize dual frequency plasma generation plasma is generated using both FIF RF and low frequency radio frequency (LF RF). Example low-frequency RF frequencies may include, but are not limited to, frequencies between 50 kHz and 700 kHz. Example high frequency RF frequencies may include, but are not limited to, frequencies between 1.8 MHz and 2.45 GHz, In some embodiments LF frequency is 430 KHz and high frequency is 13.56 MHz

The silicon-containing precursor and the reactant can be introduced in any order. In some embodiments, the silicon-containing precursor is introduced first into the process chamber and is allowed to form a layer (e.g.. adsorption-limited layer) on the surface of the substrate. Next, non surface-bound precursor is removed from the process chamber (e.g., by purging and/or evacuation) and the substrate having a layer of silicon-containing precursor on the surface is exposed to the reactant (where the reactant may be activated in a plasma). The reaction may proceed spontaneously after introduction of the reactant or may occur after additional ,iictivzition. Then the process chamber may be purged andloi evacuated to remove the reaction byproducts andior excess reactant, and the entire process may be repeated as many times as necessary to form a layer of desired thickness,

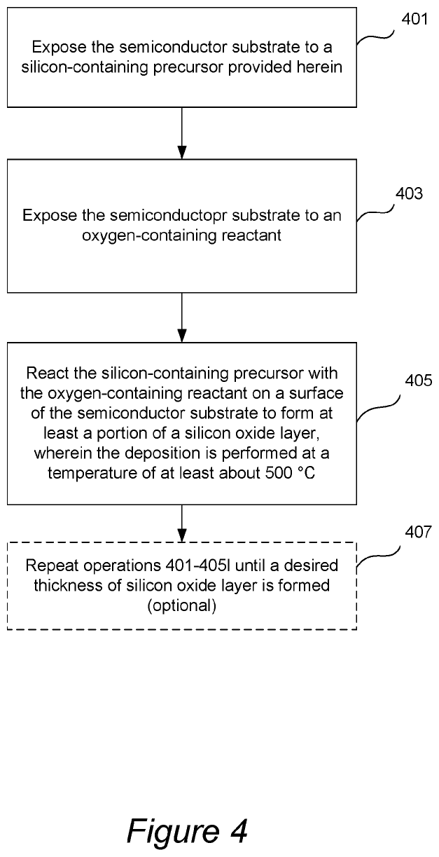

A process flow diagram for an exemplary method of depositing silicon oxide is shown in FIG. 4. The process starts in operation 401 by exposing the semiconductor substrate to a silicon-containing precursor provided herein. The semiconductor substrate can be exposed to any of the silicon-containing precursors provided herein (including to mixtures of silicon-containing precursors provided herein). In some embodiments the silicon-containing precursor is introduced into the process chamber housing the semiconductor substrate in a mixture with a carrier gas (e.g., helium, argon, N₂, etc.), here the process chamber is maintained at a temperature of at least about 500° C., such as at least about 550° C. such as about 500-800° C. about 550-700° C. The silicon-containing precursor is allowed to form a layer (e.g., an adsorption-limited layer) on the surface of the substrate. Next, in operation 403, the semiconductor substrate is exposed to an oxygen-containing, reactant. For example an oxygen-containing reactant (including a single reactant and mixtures of different reactants) max be introduced into the process chamber housing the semiconductor substrate, optionally with a carrier gas. Examples of oxygen-containing reactants include without limitation O₂, O₃, H₂O, H₂O₂, and N₂O. Examples of carrier gases include without limitation helium, argon and N₂. Next, in operation 405, the silicon-containing precursor reacts with the reactant on the surface of the semiconductor substrate to form. at least a portion of the silicon oxide layer, where the deposition Oil of steps 401-405) are performed at a temperature of at least about 500° . The reaction may be thermal or plasina-assisted. Next, m operation 407 steps 401-405 are optionally repeated as many times as necessary until a desired thickness of the silicon oxide layer is formed.

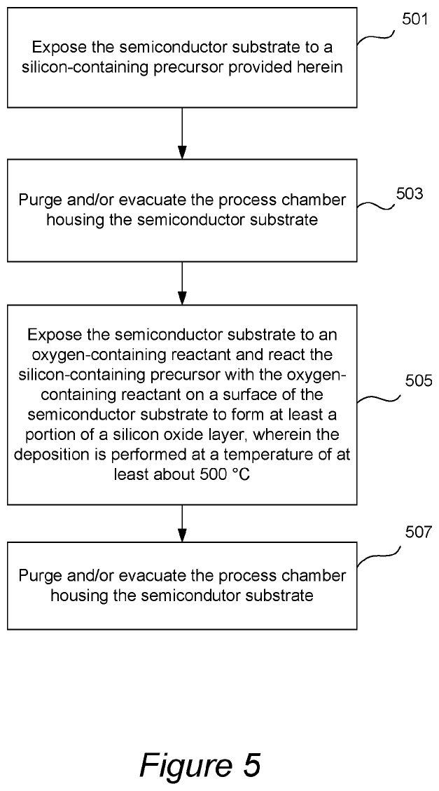

In some embodiments, the reaction is limited to the surface of the substrate by removing the non surface-hound silicon-containing precursor and/or reactant from the process chamber by purging and/or evacuation. One implementation is illustrated by the process flow diagram shown in FIG. 5. The process starts in 501 by exposing the semiconductor substrate to a silicon-containing precursor provided herein. Next, in 503, the process chamber housing the semiconductor substrate is purged and or evacuated. The purging and/or evacuation are performed to remove the non surface-bound silicon-containing precursor. In some embodiments the process chamber is purged with an inert gas, such as argon, helium, N₂, etc. Next, in operation 505, the semiconductor substrate is exposed to an oxygen-comaining reactant rind the silicon-containing precursor is allowed to react with the oxygen-containing reactant on the surface of the substrate to form at least a portion of silicon oxide. The reaction may be either thermal or plasma-assisted. Next., in operation 507, the process chamber is purged and/or evacuated. All steps 501-507 in this embodiment are conducted at a temperature of at least about 500° C.. The deposition cycle, including steps 501-507 may be repeated is many times as necessary to provide silicon oxide of desired thickness.

In some embodiments a single silicon-containing precursor is used for both thermal deposition and for plasma enhanced deposition. The precursor may serve for deposition of layers having the same or different compositions. In some embodiments thermal deposition and plasma enhanced deposition are performed sequentially on a single substrate. For example, if the substrate initially contains an exposed surface that can be easily damaged by plasma- the deposition of a silicon-contains ng layer may start thorn all in an absence of plasma Examples of surfaces that can be easily damaged, by plasma include but are not limited to Si, a-Si, a-C, a polymer composite material such as those used for lithography, or metal or metalloid layers including but not limited to Ga, In, W, Mo, Cu, Ni, Co, Sb, Sn, and Ag or binary or ternary materials including. but not limited to MoS₂, WS₂, MoSe₂, WSe₂, MoTe₂, InGaS, InGaAs, and InGaSb. Next, after the surface of the substrate is coated with the less-delicate silicon-containing material, plasma-enhanced deposition of the same ₛilicoₙ-eₒᵣitaMinoᵣ material may .follow. In other embodiments the process starts by plasma- enhanced deposition and follo^{,}ws by a thermal deposition in an absence of plasma The depositions alay be performed using silicon-containing precursors and deposition methods described herein.

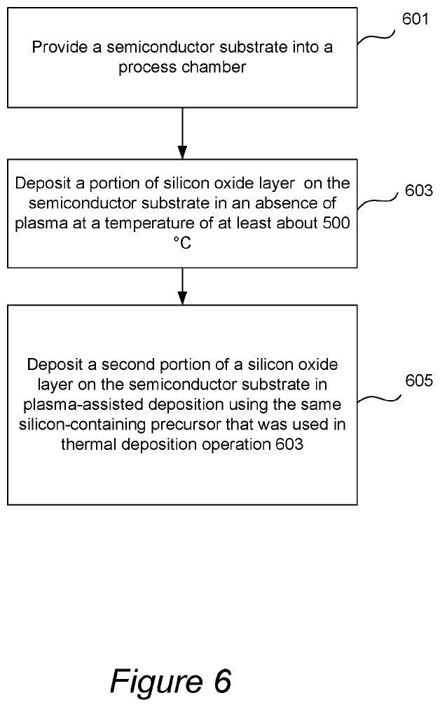

An exemplary process flow diagram for deposition of silicon oxide is shown in FIG. 6. In operation 601 a semiconductor substrate is provided to a process chamber. For example, a semiconductor substrate having a layer of a plasma-sensitive material on it surface may be provided to a process chamber of a PEALD apparatus. Next, in operation 603, a portion of the silicon oxide layer is deposited onto the substrate by ALD in an absence of plasma at a temperature of at least about 500° C. For example, the silicon oxide in this thermal step can be deposited directly onto the plasma-sensitive material to prevent any plasma damage to that layer. The deposition may be conducted, for example, using any of the silicon-containing precursors provided herein. Next, in operation 605 a second pot non of die silicon oxide layer is deposited onto the substrate in plasma-assisted deposition using the same silicon-containing precursor that was used in thermal deposition 603. In some embodiments plasma enhanced deposition 605 is performed in the same process chamber as thermal deposition 603. In other embodiments the substrate is transfened from a thermal deposition station to a plinima enhanced deposition station within one module housing both. stations without exposing the semiconductor substrate to ambient atmosphere. In some embodiments plasma assisted deposition is performed at a temperature of at least about 500° C. In same embodiments depositions 603 and 605 are thermal and plasma enhanced ALD operations that involve reactions of the silicon-containing precursor with an oxygen-containing reactant on the surface of the substrate as described in FIGS. 4 and 5. In some embodiments the oxygen-containing reactants used during thermal and plasma enhanced depositions are different. In one example, the oxygen-containing reactant used in thermal deposition at high tempennurc is water, whereas the oxygen-eatuaining reactant used in plasma enhanced deposition a high temperature is a mixture of O₂ and N₂O.

While the methods were illustrated using silicon oxide deposition as an example, it is understood that other silicon-containing materials can be similarly deposited at high temperature using silicon-containing precursors described herein, by using an appropriate reactant, For example silicon nitride can be deposited by using a nitrogen-containing reactant (e.g., NH₃, hydrazine, N₂), for a high temperature surface reaction with the silicon-containing precursor, where the reaction may be thermal or plasma-assisted, Silicon ox nitride; m.ay be deposited by using a process gas containing an oxygen-containing and a nitrogen-containing reactant for a high temperature surface reaction with a silicon-containing precursor.

### Apparatas

The deposition methods described herein can be carried out in a variety of tipparatuses. A suittible. tipparatus includes an prcieessing chamber having one or more inlets for introduction of reactants, a substrate holder in the process chamber configured to hold the substrate in place during deposition, and, optionally, a plasma generating mechanism configured for generating a plasma in a process gas. When high temperature deposition is performed, the apparatus further includes a heater configured for heating the process chamber to desired temperature. The apparatus maty include as controller having program instructions for causing any of the method steps described herein. The deposition methods described herein may be carried out in corresponding ALD apparatuses available from Lam Research Corp. of Fremont, Calif., such as Striker® tools. Thermal deposition can he carried out in an apparatus with or without plasma generating mechanism. Plasma enhanced deposition is carried out in an apparatus having a plasma generating mechanism, were the plasma generating mechanism .may be configured to generate plasma remotely (outside the process chamber housing the substrate) or directly (inside the process chamber housing the substrate). In some embodiments the apparatus includes at least two process chambers or at least two stations within one process chamber, where one is configured for thermal deposition, and the other is configured for plasma enhanced deposition.

In some embodiments the apparatus includes, a controller having program instructions that include instructions for: causing an introduction of a silicon-contaning precursor to the processing chamber, wherein the precursor is any of the precursors described herein; and causing as reaction between the silicon-containing precursor and a reactant to form a layer of silicon-containing material on a substrate at a temperature of at least about 500° C., where the reaction is configured to be conducted in a surface limited manner. For example, program instructions may include instructions for causing purging after introduction of each of the silicon-containing precursor and a reactant, and instructions for causing repeated sequential introductions of silicon-containing precursor and a reactant to the processing chamber to deposit a layer of desired thickness. In some ctnbodiments the instructions for causing exposure of the substrate to an oxygen-containing reactant, optionally in a plasma, are provided. Generally, the controller may include program instructions for causing any of the methods described herein.

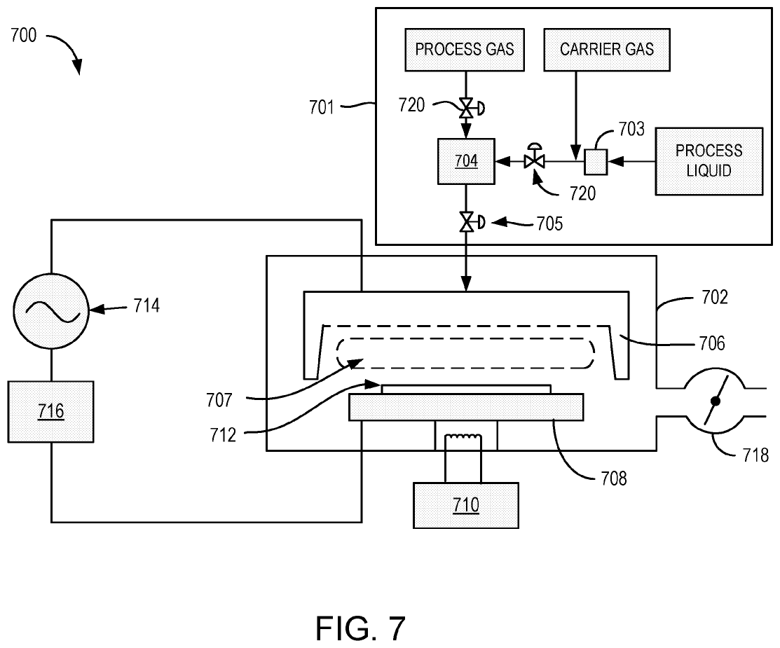

An example of a deposition apparatus suitable for depositing silicon-containing films using provided methods is shown in FIG. 7. FIG. 7 schematically shows an embodiment of a process station 700 that may be used to deposit material using atomic layer deposition (ALD) which may be thermal or plasma enhanced. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers.

Process station 700 fluidly communicates with reactant delivery system 701 for delivering process gases to a distribution showerhead 706. Reactant delivery system 701 includes a mixing vessel 704 for blending, and/or conditioning process gases for delivery to showerhead 706. One or more mixing vessel inlet valves 720 may control introduction of process gases to mixing vessel 704. Similarly, a showerhead inlet 705 may control introduction of process gasses to the showerhead 706.

Some silicon-containing precursors may be stored in solid or liquid form prior to vaporization and subsequent delivery to the process station. For example, the embodiment of FIG. 7 includes a vaporization point 703 for vaporizing solid reactant to be supplied to mixing vessel 704. In some embodiments, vaporization point 703 may be a heated vaporizer. In some embodiments a flow of an inert gas is passed over the heated solid silicon-containing precursor, or bubbled through the heated liquid silicon-containing precursor, under subatmospheric pressure, and carries the precursor vapor to the process chamber. The precursor vapor produced from such vaporizers may condense in downstream delivery piping. Exposure of incompatible gases to the condensed reactant may create small particles. These small particles mays clog piping, impede valve operation, contaminate substrates, etc. Some approaches to addressing these issues involve sweeping and/or evacuating the delivery piping, to removci residual reactant. However, sweeping the delivery piping may increase process station cycle time, degrading process station throughput. Thus, in some. embodiments, delivery piping downstream of vaporization point 703 may be heat traced. In some examples, mixing vessel 704 may also be heat traced. In one non-limiting example, piping downstream of vaporization point 703 his an Mcretsing to mperatutv profile extending from approximately. 100° C. to approximately 200° C. at mixing vessel 704.

Showerhead 706 distributes process gases toward. substrate 712. In the embodiment shown in FIG. 7, substrate 712 is located beneath showerhead 706, and is shown resting on a pedestal 708. It will be appreciated that showerhead 706 may have any suitable shape, and may have any suitable number and arrangement of ports for distributing processes gases to substrate 712. While not explicitly shown, in some embodiments the showerhead 706 is a dual plenum showerhead that includes at least two types of conduits, where the first type of conduit is dedicated to delivery of silicon-containing precursor vapor, and the second type of conduit is dedierued to delivery of the reactant. In these embodiments the silicon-containing precursor and the reactant are not allowed to mix in the conduits prior to entry to the process chamber, and do not share the conduits if delivered to the chamber consecutively.

In some embodiments, a microvolame 707 is located beneath showerhead 706 Performing an ALD process in a microvolume rather than in the entire volume of a process station may reduce reactant exposure and sweep times, may reduce times tbr altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput, While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and, to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within mierovolume 707. In some embodiments, microvolume 707 may completely enclose substrate 712 as well as a portion of pedestal 708 to create a region of high flow impedanc.e during a deposition process.

Optionally, pedestal 708 may be lowered andSor raised during portions the deposition process to modulate process pressure, reactant concentration, etc., within mierovolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolt:tine variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the preset:a disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering; a plasma In other embodiments apparatuses without a plasma generator are used for depositing silicon-containing films using provided methods the-finally. In some embodiments, the plasma energy may be controlled by controlling one or more of a process station pressure, a gas concentration, a radio frequency (RF) source power, an RF source frequency, and a plasma power pulse timing. for example, RF power supply 714 and twitching network 716 may be operated at any suitable power to form a plasm having a desired composition of radical species. Likewise, RF power supply 714 may provide RF power of any suitable frequency. In some embodiments, RF power supply 714 may be configured to control high- and low-frequency RF power sources independently of one another, Example low-frequency RE frequencies nny include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors te,g., VI probes). In another scenario, plasma density andlor process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via inputioutput control (IOC) sequencing instructions. In one example, the instructions fin setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may he further subdivided and/or iterated in any suitable way within the scope of the present disclosure.

Pedestal 708 is typically temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by vitrying a flow rate of one or more gases introduced to process station 700.

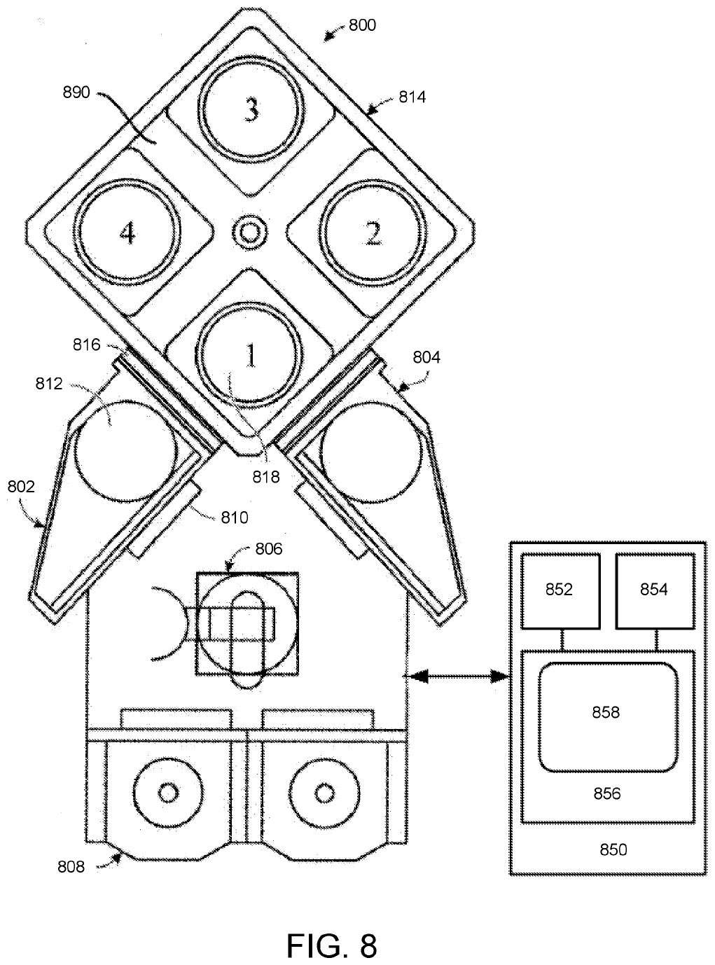

FIG. 8 shows a schematic view of an embodiment of a multi-station processing tool 800 with m inbound Ioad lock 802 and an outbound load lock 804, either or both of which may comprise a remote plasma source. Such tool may be used for processing the substrates using the methods provided herein. A robot 806, at atmospheric pressure, is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 comprises a remote plasma source, the wafer may be exposed to a remote plasma treatment in the load lock prior to being introduced into a processing chamber 814. Further, the wafer also may be heated. in the inbound load loch 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 comprises four process stations, numbered from 1 to 4 in the embodiment shown in FIG. 8. Each station has a heated pedestal (shown at 818 for station 1), and gas line inlets, It will be appreciated that in some embodiments, each process station may have different or multiple purposes. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a wafer handling system 890 far transferring wafers within processing chamber 814. In some embodiments, wafer handling system 890 may transfer wafers between various process stations and: or between a process station and a load lock, It will be appreciated that any suitable wafer handling system may he employed, Non-limiting examples include wafer carousels and wafer handling robots. FIG. 8 also depicts an embodiment of a system controller 850 employed to control process conditions and hardware states of process to 800. System controller 850 may include one or more memory devices 856, one or more mass storage devices 854, and one or more processors 852. Processor 852 may include a CPU or computer, analog and/or digital inputloutput connections, stepper motor controller boards, etc.

In some embodiments, system controller 850 controls all of the activities of process tool 800. System controller 850 executes system control software 858 stored in mass storage device 854, loaded into meteor y device 856, and executed on processor 852. System control software 858 may include instructions for controlling the timing, mixture of gases, chamber andlor station pressure, chamber andlor station temperature, purge conditions and timing wafer temperature, RF power levels RF frequencies:, substrate., pedestal, chuck and/or susceptor position, and other parameters of a particular process performed by process tool 800. System control softwam 858 may be configured in any suitable way. For example, various process tool component subroutines or control objects may be written to control operation of the process tool components necessary to carry out various process tool processes in accordance with the disclosed methods. System control software 858 may be coded in tiny suitable computer readable programming language.

In some embodiments, system control software 858 may include inputioutput control (IOC) sequencing instructions for controlling the various parameters described above. For example, each phase of an ALD process may include one or more instructions for execution by system controller 850. The instructions for setting process conditions for for ALD process phase may be included in a corresponding ALD recipe phase. In same embodiments, the ALD recipe phases may be sequentially arranged, so that all instrucdons for a ALD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning prograin a proeess gas control program a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the tempertiture of the substrate within any of the disclosed ranges.

A plasma control program may include code for setting RF power levels and frequencies applied to the process electrodes in one or inure process stations, for example using any of the RF power levels disclosed herein. The plasma control program may also include code for controlling the duration of each plasma exposure.

In some embodiments, there may he a user interface associated with system controller 850. The user interface may include a display screen, gaphical software displays of the apparatus en dlor process conditions, tind user input devices such its pointing devices, keyboards, touch screens, microphones, etc.

In some embodiments, parameters adjusted by system controller 850 may relate to process conditions. Non-limiting, examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors such as manometers), thermocouples, etc. Appropriately programmed feedback and control algorithms may be used with data from these sensors to maintain process conditions.

The controller may include program instructions for causing any of the steps of the method described herein. in some embodiments program instructions include instmctions for causing deposition of a portion of a silicon-contzhning layer in an absence of plasma in one station of a reactor; transferring the substrate to a second station within the reactor and depositing a second portion of the silicon-containing layer in a plasma-enhanced deposition, without exposing the substrate to atmospheric moisture and oxygen. In other embodiments program instructions for causing plasma-free deposition followed by plasma enhanced deposition in one station of an apparatus are provided.

Any suitable chamber may be used to implement the disclosed embodiments. Example deposition apparatuses include, but are not limited to, apparatus from the Striker® product family, available from Lam Research Corp, of Fremont, Calif., or any of a variety of other commercially available processing systems. Two or more of the stations may pertbrm the same functions. Similarly, two or more stations may perform different functions. Each station can be designed/configured to perform a particular function/method as desired.

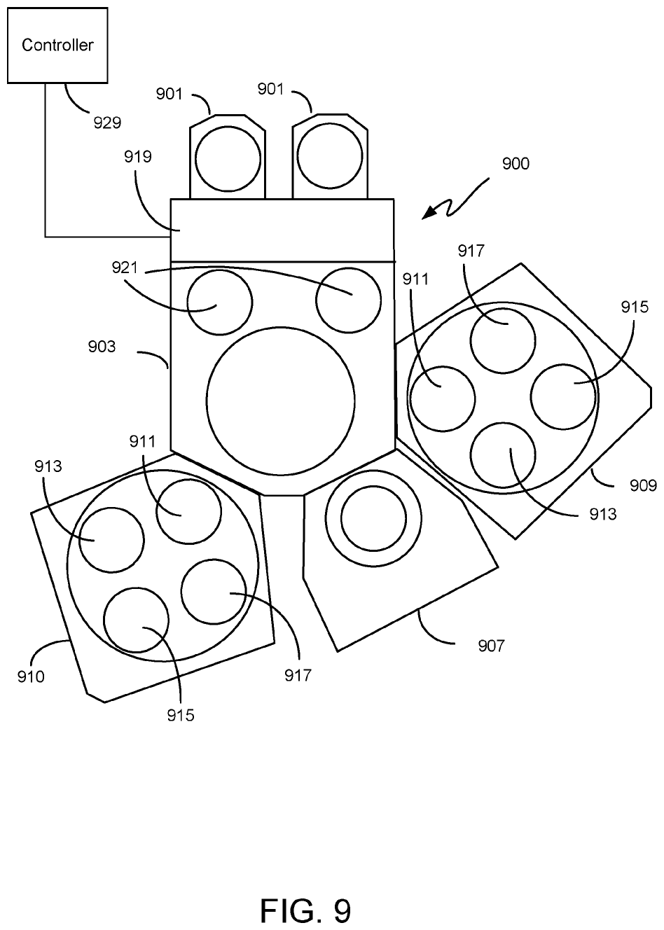

FIG. 9 is a block diagram of a processing system suitable for conducting thin film deposition processes in accordance with certain embodiments. The system 900 includes a transfer module 903. The transfer module 903 provides a clean, pressurized environment to minimize risk of contamination of substrates being processed as they are moved. between various reactor modules. Mounted on the transfer module 903 are two multi-station reactors 909 and 910, each capable of performing atomic layer deposition (ALD) according to certain embodiments. Reactors 909 and 910 may it multiple stations 911, 913, 915 and 917 that may sequentially or non-sequentially perform operations in accordance with disclosed embodiments. The stations may include a heated pedestal or substrate support, one or mote gas inlets or showerhead or dispersion plate.

Also mounted on the transfer module 903 may be one or more single or multi-station modules 907 capable of performing plasma or chemical (non-plasma) pre-cleans, or any other processes described in relation to the disclosed methods. The module 907 may in some cases be used for various treatments to, for example, prepare a substrate for a deposition process. The module 907 may also be designed configured to perform various other processes such as etching or polishing. The system 900 also includes one or more wafer source modules 901, where wafers are stored before and after processing. An atmospheric robot (not shown) in the atmospheric transfer chamber 919 may first remove wafers from the source modules 901 to loadiocks 921. A wafer transfer device (thenar tilt a robot arm unit) in the transfer module 903 moves the wafers from loadlocks 921 to and among: the modules mounted on the transfer module 903.

In various embodiments, a system controller 929 is employed to control process conditions during deposition. The controller 929 will typically include one or more memory devices and one or more processors. A processor may include a CPU or computer, analog andior di ital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of t particulikr process. Other computer programs stored on memory devices associated with the controller 929 may be employed in some embodiments.

Typically there will be a user interface associated with the controller 929. The user interface may include a display screen, graphical software displays of the apparatus and/or process conditions, and user input devices such as pointing devices, keyboards, touch screens, microphones, etc.

System control logic ma he configured in any suitable way. In general, the logic can be designed or configured in hardware and/or software. The in for controlling the drive circuitry may be hard coded or provided as software. The instructions may be provided by “programming” Such progamming is understood to include logic of any form, including hard coded logic in digit it signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any cons entional computer readable programming languaae: for example, assembly language, C, C++, Pascal, Fortran, or others. Compiled of je.ct code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided b malog i.radfor digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 929 is part of a system, which may be part of the above-described examples, Such systems can include semiconductor processing equipment, including a processing tool or tools, chamber or chambers, a platform or platforms for processing, andlor specific processing components (a wafer pedestal, a gas flow system, etc.). These systems may be integrated with electronics for controlling their operation before, during, and after processina of a semiconductor wafer or substrate. The electronics may be referred to as the “controller,” which may control various components or subparts of the system or systems. The controller 929, depending on the processing requirements and. or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RE matching circuit settings, frequency settings, flow rare settings, fluid delivery settings, positional and operation settings, wafer transfers into and out of a tool and other transfer tools andlor load locks connected to or interfaced with a specific system.

Broadly speaking, the controller may be defined as electronics having various integrated circuits, logic, memory, andlor software that receive instructions, issue instructions, control operation, enable cleaning opertitions, enable endpoint measurements, and the like, the integrated circuits may include chips in the form of firmware that store program instructions, digital signal processors (DSPs), chips defined as application specific integrated circuits (ASICs), and/or one or more microprocessors, or microcontrollers that ex. cute program instructions (e.g., software), Program instructions may be instructions communicated to the controller in the form of various individual settings (or program files), defining operational ptuameters for carrying out a particular process on or for a semiconductor wafer or to a system. The operational parameters may, in some embodiments, be part of a recipe defined by process engineers to accomplish one, or more processing steps during the fabrication of one or more layers, materials, metals, oxides, silicon, silicon dioxide, surfaces, circuits, aa .dlor dies of a wafer.

The controller, in some implementations, may be a part of or coupled to a computer that is integrated with, coupled to the system, otherwise networked to the system, or a combination thereof For example, the controller may be in the “cloud” or all or a part of a thb host computer system, which can allow for remote access of the wafer processing. The computer may enable remote access to the system to monitor current progress of fabrication operations, examine a history of past fabrication operations, example trends or performance metrics from a plurality of thbrication operations, to change parameters of current processing to set processing steps to follow a current processing, or to start a new process. In some examples a remote computer (e.g. a server) can provide proscess recipes to as system over a network, which turn include a loetal network or the Internet. The remote computer may include a user interface that enables entry or programming of parameters and/or settings, which are then communicated to th.e system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more in termated circuits on a chamber in communication with one or more integrated circuits located remotely (such as at the platform level or as part of a remote computer) that combine to control a process on the chamber.

Without limitation, example systems may include, a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, tiara ion implantation chamber or module, a track chamber or module, arid any other semiconductor processing systems that may be associated or used in the fabrictition and for manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools kcated throughout a factory, a main computer, another controller, or tools used in material transport that bring containers of wafers to and from tool locations and/or load ports in a semiconductor manufacturing factory.

### Further Implementations

The apparatus and processes described herein may be used in conjunction with lithographic patterning tools or processes, for example, for the :fabrication or Manufacture of semiconductor devices, displays, LEDs, photovoltaic panels, and the like. Typically, though not necc:ssarily, such apparatus arid processes sill he used or conducted together in a common fabrication facility. Lithographic patterning of a film typically comprises sonic or all of the fbIlowing steps, each step enabled with a number of possible tools: (1) application at photoresist on a work piece, i.e-, a substrate, using a spin-on or spray-on tool, (2) eurillg cif photoresist using a hot plate or furnace or UV curing tool; (3) exposing the photoresist to visible or UV or x-ray light with a tool such as a wafer stepper; (4) developing the resist so as to seiectiveiy remove resist and thereby pattern it casing a tool such as a wet bench; (5) iTansferring the resist patteili into an underlying film, or work piece by using a dry or plasma-assisted etching tool; and (6) removing the resist using a tool such as an RF or microwave plasma resist stripper.

1. A method of forming a silicon-containing layer on a semiconductor substrate, the method comprising:
(a) exposing the semiconductor substrate to a silicon-containing precursor in a process chamber, wherein the silicon-containing precursor is a compound that has:
at least one Si—Si bond;
at least one Si—X bond, wherein X is selected from the group consisting of a halogen, triflate, tosylate, CN, N₃, and NR₁R₂, wherein R₁ and R₂ are independently selected from the group consisting of H, and an alkyl, wherein R₁ and R₂ are either linked to form a cyclic ring structure or not linked; and
at least one Si-R bond, wherein R is selected from the group consisting of H, and an alkyl;
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.

2. The method of claim 1, wherein the reactant is an oxygen-containing reactant and wherein (c) comprises reacting the silicon-containing precursor with the oxygen-containing reactant in an absence of plasma to form a silicon oxide layer.

3. The method of claim 1, further comprising purging the process chamber between exposures of the semiconductor substrate to the silicon-containing precursor and the reactant.

4. The method of claim 1, wherein operations (a)-(c) are performed at a temperature of at least about about 550° C.

5. The method of claim 1, wherein the silicon-containing precursor is selected from the group consisting of: 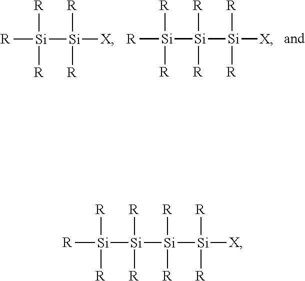
wherein each R is the same or different and is independently selected from the group consisting of H, and C1-C3 alkyl.

6. The method of claim 1, wherein the silicon-containing precursor is selected from the group consisting of: 1-chlorodisilane, 1-dimethylaminodisilane, 1-diethylaminotrisilane, 1-bromotetrasilane, and 1,2-bis(diisopropylamino)disilane.

7. The method of claim 1, wherein R is an alkyl, and wherein the silicon-containing precursor does not include Si—H bonds.

8. The method of claim 1, further comprising repeating operations (a)-(c) until the silicon-containing layer reaches a target thickness.

9. The method of claim 1, wherein the method comprises depositing a first portion of the silicon-containing layer in an absence of plasma and a second portion of the silicon-containing layer using a plasma-assisted reaction while using the same silicon-containing precursor for both thermal and plasma-assisted deposition.

10. A method of forming a silicon-containing layer on a semiconductor substrate, the method comprising:
(a) exposing the semiconductor substrate to a silicon-containing precursor in a process chamber, wherein the silicon-containing precursor is a compound that has:
at least one silicon atom that forms bonds with at least two nitrogen atoms, wherein the at least two nitrogen atoms are linked to form a cyclic ring;
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.

11. The method of claim 10, wherein the silicon-containing precursor is a compound selected from the group consisting of: 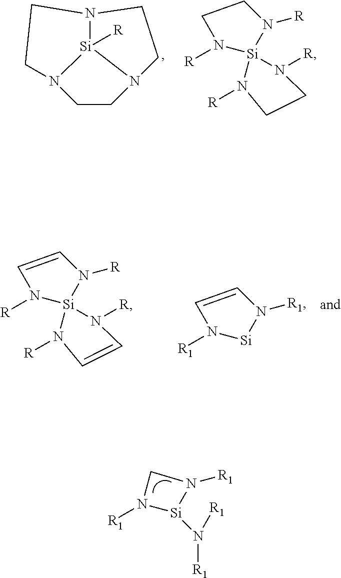
wherein each R is the same or different and is independently selected from the group consisting of H, and alkyl, and wherein each R₁ is the same or different and is an alkyl.

12. The method of claim 10, wherein the reactant is an oxygen-containing reactant and wherein (c) comprises reacting the silicon-containing precursor with the oxygen-containing reactant in an absence of plasma to form a silicon oxide layer.

13. The method of claim 10, further comprising purging the process chamber between exposures of the semiconductor substrate to the silicon-containing precursor and the reactant.

14. The method of claim 10, wherein operations (a)-(c) are performed at a temperature of at least about greater than about 550° C.

15. The method of claim 10, further comprising repeating operations (a)-(c) until the silicon-containing layer reaches a target thickness.

16. The method of claim 10, wherein the method comprises depositing a first portion of the silicon-containing layer in an absence of plasma and a second portion of the silicon-containing layer using a plasma-assisted reaction while using the same silicon-containing precursor for both thermal and plasma-assisted deposition.

17. A method of forming a silicon-containing layer on a semiconductor substrate, the method comprising:
(a) exposing the semiconductor substrate to a silicon-containing precursor in a process chamber, wherein the silicon-containing precursor is a compound that has:
at least one nitrogen atom that forms bonds with at least two silicon atoms;
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.

18. The method of claim 17, wherein the silicon-containing precursor is: 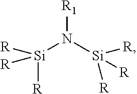
wherein each R is the same or different and is independently selected from the group consisting of H, and alkyl, and wherein each R¹ is independently selected from the group consisting of H, alkyl, and Si(R²)₃, wherein each R² is independently selected from the group consisting of H, and an alkyl.

19. The method of claim 17, wherein the silicon-containing precursor is:

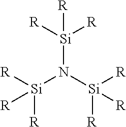

20. The method of claim 17, wherein the silicon-containing precursor is selected from the group consisting of tris(trimethylsilyl)amine, trisilylamine, isopropyl(disilyl)amine, ethyl-bis(trimethylsilyl)amine, disilylhydrazine.

21. The method of claim 17, wherein the reactant is an oxygen-containing reactant and wherein (c) comprises reacting the silicon-containing precursor with the oxygen-containing reactant in an absence of plasma to form a silicon oxide layer.

22. The method of claim 17, further comprising purging the process chamber between exposures of the semiconductor substrate to the silicon-containing precursor and the reactant.

23. The method of claim 17, wherein operations (a)-(c) are performed at a temperature of at least about greater than about 550° C.

24. The method of claim 17, further comprising repeating operations (a)-(c) until the silicon-containing layer reaches a target thickness.

25. The method of claim 17, wherein the method comprises depositing a first portion of the silicon-containing layer in an absence of plasma and a second portion of the silicon-containing layer using a plasma-assisted reaction while using the same silicon-containing precursor for both thermal and plasma-assisted deposition.

26. A method of forming a silicon-containing layer on a semiconductor substrate, the method comprising:
(a) exposing the semiconductor substrate to a silicon-containing precursor in a process chamber, wherein the silicon-containing precursor is a compound that has:
at least one silicon atom that forms a bond with a moiety selected from the group consisting of —N₃, —CN, —OTf (triflate), and —OTs (tosylate);
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.

27. The method of claim 26, wherein the silicon-containing precursor is:
SiXₙRₘ, wherein each X is independently selected from the group consisting of —N₃, —CN, —OTf (triflate), and —OTs (tosylate), each R is independently selected from the group consisting of H, an alkyl, and NR¹R², wherein each Rl and R² is independently selected from the group consisting of H, and an alkyl, wherein W¹ and R² are either linked to form a cyclic ring structure or not linked, and wherein n is 1-3, m is 1-3, and n+m is 4.

28. The method of claim 26, wherein the reactant is an oxygen-containing reactant and wherein (c) comprises reacting the silicon-containing precursor with the oxygen-containing reactant in an absence of plasma to form a silicon oxide layer.

29. A method of forming a silicon-containing layer on a semiconductor substrate, the method comprising:
(a) exposing the semiconductor substrate to a silicon-containing precursor in a process chamber, wherein the silicon-containing precursor is a compound that has:
at least one silicon atom that forms bonds with at least two oxygen atoms, wherein the at least two oxygen atoms are linked to form a cyclic ring;
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.

30. The method of claim 29, wherein the two oxygen atoms are derived from a 13- diketonate moiety.

31. A method of forming a silicon-containing layer on a semiconductor substrate, the method comprising:
(a) exposing the semiconductor substrate to a silicon-containing precursor in a process chamber, wherein the silicon-containing precursor is a compound that has:
at least one silicon atom that is part of a cyclic ring;
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.

32. The method of claim 31, wherein the silicon-containing precursor is selected from the group consisting of compounds 12, 13, 14, and 15.

33. The method of claims 1, wherein the silicon-containing layer is selected from the group consisting of silicon nitride, silicon oxynitride, silicon carbide, and silicon oxycarbide.

34. The method of claim 1, wherein the silicon-containing precursor is SiₙR₍₂ₙ₊₁₎X, wherein n is selected from 2 to 10, and wherein each R is the same or different and is independently selected from the group consisting of H, an alkyl, an alkenyl, and an alkynyl.

35. The method of claim 1, wherein the silicon-containing precursor comprises at least one silicon atom that is part of a cycle.

36. The method of claim 1, further comprising:
applying photoresist to a semiconductor substrate;
exposing the photoresist to light;
patterning the photoresist;
transferring the pattern to the semiconductor substrate; and
selectively removing the photoresist from the semiconductor substrate.

37. An apparatus for depositing a silicon-containing layer on a semiconductor substrate, the apparatus comprising:
a process chamber configured for housing the semiconductor substrate, wherein the process chamber includes an inlet for introduction of a silicon-containing precursor; and a controller comprising program instructions for causing deposition of the silicon-containing layer on the semiconductor substrate, wherein the program instructions comprise instructions for causing the steps of:
(a) exposing the semiconductor substrate to the silicon-containing precursor in the process chamber, wherein the silicon-containing precursor is a compound that has:
at least one Si—Si bond;
at least one Si—X bond, wherein X is selected from the group consisting of a halogen, triflate, tosylate, CN, N₃, and NR₁R₂, wherein R₁ and R₂ are independently selected from the group consisting of H, and an alkyl, wherein R₁ and R₂ are either linked to form a cyclic ring structure or not linked; and
at least one Si—R bond, wherein R is selected from the group consisting of H, and an alkyl;
(b) exposing the semiconductor substrate to a reactant in the process chamber; and
(c) reacting the silicon-containing precursor with the reactant on a surface of the semiconductor substrate to form at least a portion of the silicon-containing layer, wherein operations (a)-(c) are performed at a temperature of at least about 500° C.,
or instructions for causing the steps of:
(d) exposing the semiconductor substrate to a silicon-containing precursor in a process chamber, wherein the silicon-containing precursor is a compound that has:
at least one silicon atom that forms bonds with at least two nitrogen atoms, wherein the at least two nitrogen atoms are linked to form a cyclic ring;
(e) exposing the semiconductor substrate to a reactant in the process chamber; and
(f) reacting the silicon-containing precursor with the reactant on a surface of the semiconductor substrate to form at least a portion of the silicon-containing layer, wherein operations (d)-(f) are performed at a temperature of at least about 500° C.,
or instructions for causing the steps of:
(g) exposing the semiconductor substrate to a silicon-containing precursor in a process chamber, wherein the silicon-containing precursor is a compound that has:
at least one nitrogen atom that forms bonds with at least two silicon atoms;
(h) exposing the semiconductor substrate to a reactant in the process chamber; and
(i) reacting the silicon-containing precursor with the reactant on a surface of the semiconductor substrate to form at least a portion of the silicon-containing layer, wherein operations (g)-(i) are performed at a temperature of at least about 500° C.,
or instructions for causing the steps of:
(j) exposing the semiconductor substrate to a silicon-containing precursor in a process chamber, wherein the silicon-containing precursor is a compound that has:
at least one silicon atom that forms a bond with a moiety selected from the group consisting of —N₃, —CN, —OTf (triflate), and —OTs (tosylate);
(k) exposing the semiconductor substrate to a reactant in the process chamber; and
(l) reacting the silicon-containing precursor with the reactant on a surface of the semiconductor substrate to form at least a portion of the silicon-containing layer, wherein operations (j)-(l) are performed at a temperature of at least about 500° C.,
or instructions for causing the steps of:
(m) exposing the semiconductor substrate to a silicon-containing precursor in a process chamber, wherein the silicon-containing precursor is a compound that has:
at least one silicon atom that forms bonds with at least two oxygen atoms, wherein the at least two oxygen atoms are linked to form a cyclic ring;
(n) exposing the semiconductor substrate to a reactant in the process chamber; and
(o) reacting the silicon-containing precursor with the reactant on a surface of the semiconductor substrate to form at least a portion of the silicon-containing layer, wherein operations (m)-(o) are performed at a temperature of at least about 500° C.,
or instructions for causing the steps of:
(p) exposing the semiconductor substrate to a silicon-containing precursor in a process chamber, wherein the silicon-containing precursor is a compound that has:
at least one silicon atom that is part of a cyclic ring;
(q) exposing the semiconductor substrate to a reactant in the process chamber; and
(r) reacting the silicon-containing precursor with the reactant on a surface of the semiconductor substrate to form at least a portion of the silicon-containing layer, wherein operations (p)-(r) are performed at a temperature of at least about 500° C. 11 Application No unknown
